(19) United States
(12) Patent Application Publication
(10) Pub. No.: US 2014/0225605 A1
(43) Pub. Date: Aug. 14, 2014

(54) Mtj three-axis magnetic field sensor and encapsulation method thereof

(71) Applicants: Xiaofeng Lei, Zhangjiagang (CN); Xiaojun Zhang, Zhangjiagang (CN); Wei Li, Zhangjiagang (CN); Songsheng Xue, Zhangjiagang (CN)

(72) Inventors: Xiaofeng Lei, Zhangjiagang (CN); Xiaojun Zhang, Zhangjiagang (CN); Wei Li, Zhangjiagang (CN); Songsheng Xue, Zhangjiagang (CN)

(73) Assignee: Multidimension Technology Co., Ltd, Zhangjiagang (CN)

(21) Appl. No.: 14/239,859

(22) PCT Filed: Aug. 27, 2012
(86) PCT No.: PCT/CN2012/080607

§ 371 Date: Feb. 20, 2014

(30) Foreign Application Priority Data
Aug. 30, 2011 (CN) 201110251904.8

(51) Int. Cl. G01R 33/09; G01R 3/00

(52) U.S. Cl. CPC G01R 33/098; G01R 3/00
USPC 324/252; 29/592.1

(57) ABSTRACT

The present invention discloses a MTJ triaxial magnetic field sensor, comprising an X-axis bridge sensor that has a sensing direction along an X-axis, a Y-axis bridge sensor that has a sensing direction along a Y-axis, a Z-axis sensor that has a sensing direction along a Z-axis, and an ASIC chip connected with and matched to the X-axis, Y-axis, and Z-axis sensor chips. The Z-axis sensor includes a substrate and MTJ magnetoresistive elements deposited on the substrate. The Z axis magnetic field sensor is attached to the ASIC chip along an attachment edge, and an angle is formed between the sensor side of the Z axis magnetic field sensor and the adjacent attachment edge. The attachment edge angle is an acute angle or an obtuse angle. The resulting X, Y, and Z axes are mutually orthogonal. The above design provides a highly integrated sensor with high sensitivity, low power consumption, good linearity, wide dynamic range, excellent thermal stability, and low noise.

### CROSS-REFERENCE TO A RELATED APPLICATION

This application is a 35 U.S.C. §371 national phase application of PCT/CN2012/080607, filed on Aug. 27, 2012, which claims priority to a Chinese Patent Application No. CN20110251904, filed on Aug. 30, 2011, incorporated herein by reference in its entirety.

### TECHNICAL FIELD

The present invention relates to the design of a magnetic field sensor, in particular triaxial magnetic field sensor.

### BACKGROUND ART

In recent years Magnetic Tunnel Junctions (MTJ) have begun finding acceptance in industrial applications as a new type of magnetoresistive sensor, using the Tunneling Magnetoresistance (TMR) Effect of magnetic multilayer materials. In this effect the magnitude and direction of a magnetic field applied to the multilayered film changes of the resistance of the multilayer film. The TMR effect is larger than the AMR (Anisotropic Magnetic Resistance) effect, and it also known to have better temperature stability than the Hall Effect. As a result, TMR magnetic field sensors have the advantages of higher sensitivity, lower power consumption, better linearity, wider dynamic range, better temperature characteristics, and lower noise than AMR, GMR, or Hall devices. Moreover, MTJs can be easily fabricated with existing chip manufacturing technology which facilitates the production of very small integrated magnetic field sensors.

Multi-axis magnetic field sensors generally have more than a single sensor chip integrated in the package, in order to provide vector measurement capability with good orthogonality. Because the magnetic field is a vector field, a multi-axis magnetic field sensor has a very wide range of applications, especially for electronic compass, which use biaxial or triaxial sensors for geomagnetic field measurements. As a result of this common application, simplified means of production of highly-integrated single-chip multi-axis magnetic field sensors are strongly desired.

When deposited on the same wafer, GMR and MTJ materials used for the different sensor axes have the same magnetic moments, and after annealing have the same pinned layer direction, which makes fabrication of single-chip three-axis sensors difficult. As such, the most common approach to manufacture a GMR triaxial sensor is to package an X-axis sensor, a Y-axis sensor, and a Z-axis sensor deposited on three different substrates; such a GMR triaxial sensor suffers limitations such as excessive size, high packaging cost, and it has a lower sensitivity and higher power consumption than a MTJ sensor.

As can be seen from the above, current AMR, Hall, and GMR triaxial sensors are disadvantageous in that they have excessive size, high packaging cost, lower sensitivity, higher power consumption, and the manufacturing methods are impractical.

### SUMMARY OF THE INVENTION

To resolve the above problems, the present invention provides a compact triaxial sensor with higher sensitivity and lower power consumption.

A triaxial MTJ sensor, comprising an X-axis bridge sensor with a sensing direction along a X-axis, a Y-axis bridge sensor that has a sensing direction along a Y-axis, a Z-axis sensor that has a sensing direction along a Z-axis, wherein the X-axis, the Y-axis, and the Z-axis are mutually orthogonal; an ASIC chip is connected with and matched to the X-axis bridge sensor , the Y-axis bridge sensor, and the Z-axis sensor ; said Z-axis sensor includes several interconnected magnetic sensor chips and each of the interconnected magnetic sensing chips is comprised of a substrate onto which a MTJ element is deposited, and each of the interconnected magnetic sensor chips is positioned on the ASIC chip along an attachment edge, said attachment edge is adjacent to the MTJ element edge, and it is oriented at an angle with respect to the MTJ element edge, wherein said angle is an acute angle or an obtuse angle.

Preferably, the X-axis bridge sensor is a MTJ sensor.

Preferably, wherein the Y-axis bridge sensor is a MTJ sensor.

Preferably, the X-axis bridge sensor and the Y-axis bridge sensor are connected with the ASIC chip using gold wire bonds.

Preferably, the X-axis bridge sensor and the Y-axis bridge sensor are connected with the ASIC chip using a solder bump.

Preferably, the X-axis bridge sensor and the Y-axis bridge sensor are integrated into the same chip.

Preferably, the X-axis bridge sensor is a referenced bridge sensor and the Y-axis bridge sensor is a push-pull bridge sensor.

Preferably, each of the sensing chips is connected with the ASIC chip using solder bumps.

Preferably, the Z-axis sensor includes two or four MTJ magnetic sensor chips, said MTJ sensor chips are symmetrically arranged on the ASIC chip.

A triaxial MTJ sensor packaging method, comprising the steps of
A) fabricating a X-axis bridge sensor that has a sensing direction along a X-axis and electrically connecting the X-axis sensor with an ASIC chip,
B) fabricating a Y-axis bridge sensor that has a sensing direction along a Y-axis and electrically connecting the Y-axis sensor with the ASIC chip,
C) fabricating MTJ magnetoresistive elements on a wafer, cutting said MTJ wafer obliquely to form MTJ magnetic sensor chips; placing the attachment edge of the MTJ magnetic sensor chips onto the ASIC chip; each said attachment edge is at an angle with respect to the adjacent surface of the substrate, and the angle is an acute angle or an obtuse angle; physically connecting each of the MTJ magnetic sensor chips with the ASIC chip using solder bumps; and electrically connecting the MTJ magnetic sensing elements to form a Z-axis magnetic sensor.

A MTJ three-axis sensor packaging method, comprising the steps of
A) fabricating a X-axis magnetic field sensor bridge that has a sensing direction along a X-axis and electrically connecting the X-axis sensor to an ASIC chip,
B) fabricating a Y-axis magnetic field sensor bridge that has a sensing direction along a X-axis and electrically connecting the X-axis sensor to the ASIC chip,
C) fabricating MTJ magnetoresistive elements on a wafer, etching the back side of said wafer to form a slopes; cutting the MTJ wafer to form MTJ magnetic sensor chips; placing the attachment edge of the MTJ magnetic sensor chips onto the ASIC chip; each said attachment edge is at an angle with respect to the adjacent surface of the substrate, and the angle is an acute angle or an obtuse angle; physically connecting each of the MTJ magnetic sensor chips with the ASIC chip using solder bumps; and electrically connecting the MTJ magnetic sensing elements to form a Z-axis magnetic sensor.

In order to solve the above technical problem, the technical solution adopted in the present invention uses the above structure, to achieve a high level of integration, high sensitivity, low power consumption, good linearity, wide dynamic range, good temperature performance, and low noise performance.

### BRIEF DESCRIPTION OF THE DRAWINGS

FIG. 1 is a schematic drawing of the magnetic resistance of a magnetic tunnel junction element.

FIG. 2 is a graph of the ideal output of an MTJ element.

FIG. 3 is a schematic diagram of MTJ elements electrically connected in series.

FIG. 4 is a schematic diagram of a MTJ push-pull bridge sensor.

FIG. 5 is a plot of the analog output of a MTJ push-pull bridge sensor.

FIG. 6 is a schematic diagram of a MTJ referenced bridge sensor.

FIG. 7 is simulation plot of the output of a MTJ referenced bridge sensor.

FIG. 8 is a schematic view of a type of single-chip biaxial magnetic field sensor.

FIG. 9 is a cross-sectional view of the first step of the Z-axis magnetic field sensor chip preparation method.

FIG. 10 is a view of the second step of the Z-axis magnetic field sensor chip preparation method

FIG. 11 is a view of the third step of the Z-axis magnetic field sensor chip preparation method

FIG. 12 is a view of the fourth step of the Z-axis magnetic field sensor chip preparation method

FIG. 13 is a cross-sectional view of the first step of the Z-axis magnetic field sensor chip second preparation method.

FIG. 14 is a view of the second step of the Z-axis magnetic field sensor chip second preparation method

FIG. 15 is a view of the third step of the Z-axis magnetic field sensor chip second preparation method

FIG. 16 is a view of the fourth step of the Z-axis magnetic field sensor chip second preparation method

FIG. 17 is a schematic view of the structure of the triaxial magnetic field sensor prepared using the first preparation method.

FIG. 18 is a schematic view of the structure of the triaxial magnetic field sensor prepared using the second preparation method.

In the figures, 1 is a MTJ element; 2 a magnetic pinned layer; 3 an antiferromagnetic layer; 4 a ferromagnetic layer; 5 a tunnel barrier layer; 6 a ferromagnetic free layer; 7 the ferromagnetic free layer magnetization direction; 8 the ferromagnetic pinned layer magnetization direction; 9 an applied magnetic field; 10 the sensing direction; 11 a seed layer; 12 an upper electrode; 13 the resistance of an MTJ element; 14 The low resistance value of an MTJ element; 15 the high resistance value of an MTJ element; 16 electric current; 17 a permanent magnet; 18 a substrate; 19 an ASIC chip; 20 solder bump; 21 attachment edge; 22 chip surface; 23 attachment angle; 24 MTJ magnetic sensor chip ; 25 an X-axis bridge sensor; 26 a Y-axis bridge sensor; 27 a Z-axis bridge sensor; 41 The direction of the magnetization of the free layer R1; 42 The direction of the magnetization of the free layer R2; 43 The direction of the magnetization of the free layer R3; 44 The direction of the magnetization of the free layer R4.

### DESCRIPTION OF THE PREFERRED EMBODIMENTS

Below in conjunction with the accompanying drawings 1-18 preferred embodiments of the present invention are elaborated, such that the advantages and features of the present invention are more easily understood by those skilled in the art, so that the scope of protection of the present invention is clearly defined.

Tunnel junction magnetoresistance overview:

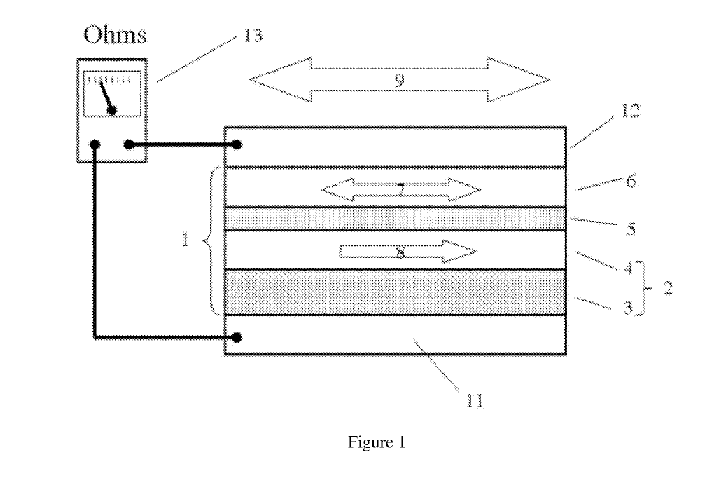

FIG. 1 is a schematic view of a standard MTJ element. The standard MTJ element 1 includes a free ferromagnetic layer 6, a ferromagnetic pinned layer 2, and a tunnel barrier layer 5 between the ferromagnetic layers. The free ferromagnetic layer 6 is composed of a ferromagnetic material, and the magnetization direction of the ferromagnetic free layer is able to change in response to an external magnetic field. The ferromagnetic pinning layer 2 has a magnetization direction that is pinned in one direction, and it does not change under general operating conditions. A ferromagnetic pinned layer 4 may be either at the top or bottom of the antiferromagnetic layer 3. The MTJ structure is usually deposited on top of a conductive seed layer 11, while an electrode 12 is usually deposited on top of the MTJ structure. The resistance of the MTJ element is measured between the seed layer 11 and the upper electrode layer 12, and its value 13 is representative of the relative orientation of the magnetizations of the ferromagnetic free layer 6 and the ferromagnetic pinned layer 2.

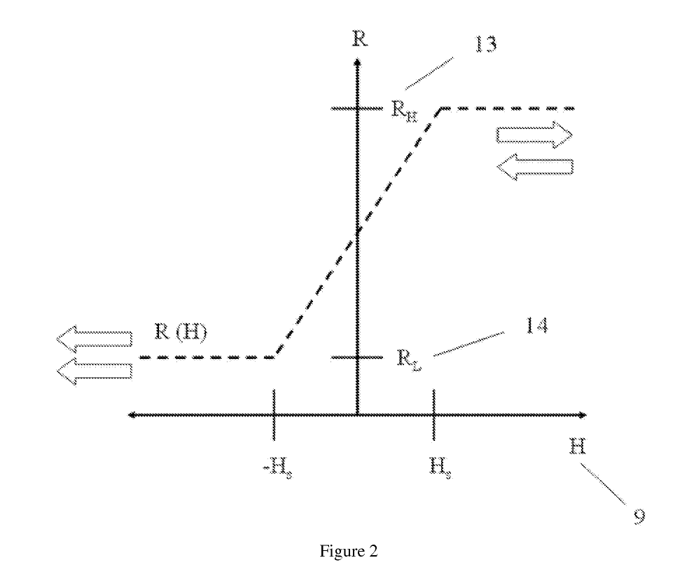

FIG. 2 is an ideal output response curve of an MTJ element, the output curve in the low-resistance state R_{L}14 and the high-impedance state R_{H}15, represent the low-resistance state 14 and the high-resistance state 15 of the saturated MTJ. When the magnetic free layer 7 magnetization direction and magnetic pinning layer 8 direction of magnetization are parallel, the measured resistance value 13 of the MTJ is the low-resistance state; when the magnetization direction of the ferromagnetic free layer 7 and the magnetization direction of the ferromagnetic pinned layer 8 are anti-parallel, the resistance value of the MTJ element 13 is the high-resistance value 15. By known techniques, the resistance of the MTJ element 1 is made linear as a function of applied magnetic field in the magnetic field range between the high-resistance state and the low resistance state, the saturation fields −Hₛ, and Hₛ then define the linear range of the MTJ element.

FIG. 3 is a schematic view of several MTJs connected in series to form a magnetoresistive element. A string of connected MTJs 1 can reduce noise and improve the stability of the sensor. In MTJ magnetoresistive element 24, the bias voltage of each MTJ 1 is decreased proportionally to the number of MTJs in the string. This reduces the current required to generate a large voltage output, thereby reducing the shot noise, and it also improves the ESD tolerance of the sensor. In addition to improving the output signal and increasing ESD tolerance, increasing the number of MTJs improves noise performance because uncorrelated random behavior of each individual MTJ element is averaged out.

Push-pull bridge sensor design:

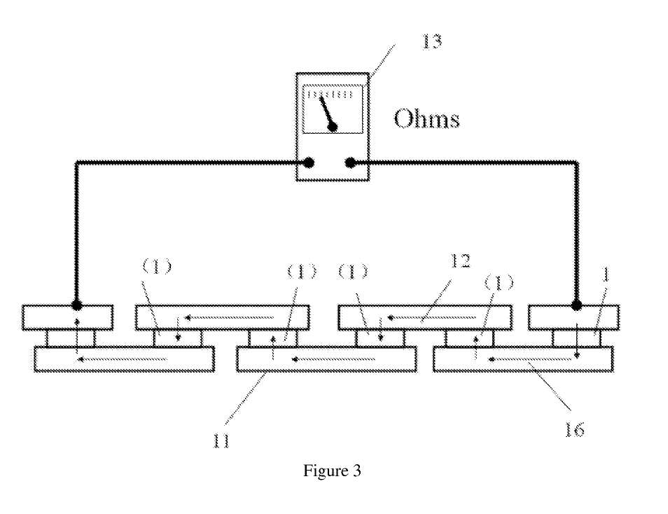

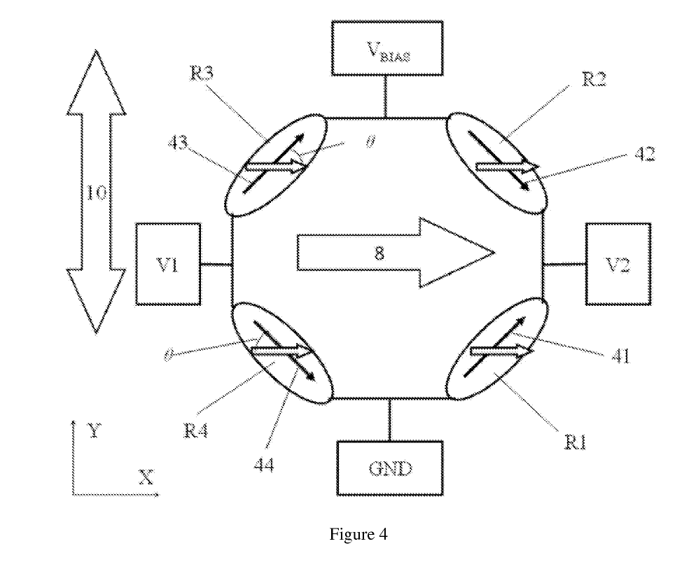

FIG. 4 is a schematic diagram of a MTJ push-pull full-bridge sensor. The four MTJ elements R1, R2, R3, and R4 are interconnected as a full-bridge, and each MTJ element is composed of one or a plurality of MTJs 1 connected in series (FIG. 2). For each of the magnetoresistive elements the magnetization direction of the pinned layer is the same, and the freelayer magnetization direction with respect to the pinned layer magnetization direction at is at an angle 9 (between 30° to 90°, and this angle θ is the same magnitude. Magnetoresistive element pairs (R1 and R3, R2 and R4) have the same free layer magnetization direction (41 and 43, 42 and 44), while magnetoresistive elements located adjacent to each other (R1 and R2, R3 and R4) have freelayer magnetization aligned in different directions (41 and 42, 43 and 44). In this specific full-bridge configuration, the sensitive direction 10 is perpendicular to the ferromagnetic pinned layer's magnetization direction 8. Because the magnetization direction of the magnetic pinned layer 8 of each of the magnetoresistive elements is the same, this push-pull full bridge sensor design can be implemented on a single chip to form a push-pull full bridge sensor, without the use of a multi-chip packaging process or the need to perform local laser heating.

When a magnetic field is applied along the sensitive direction 10, it changes the relative orientation of the freelayer magnetization relative to the pinned layer magnetization. Therefore, magnetoresistive elements such that R1 and R3 show a resistance increase while the other two magnetoresistive elements R2 and R4 show a decreasing resistance. When the magnetic field is applied in the opposite direction then R1 and R3 resistance will be reduced while R2 and R4 resistance will be increased. The use of a combination of two pairs of magnetoresistive elements that have opposite response to the applied field, that is, a pair of MTJ elements has a resistance that increases while the other has a resistance that decreases, effectively doubling the response of the bridge circuit, produces what is called a “push-pull” bridge. In the ideal case, if the resistance value of resistor R1=(R1+ΔR), R3=(R1+ΔR), R2=(R2−ΔR), and R4=(R2−ΔR), the bridge output becomes:

$$V 1 - V 2 = \frac{R 2 - Δ R - ( R 1 + Δ R )}{R 2 + R 1} {V}_{bias} \qquad ( 1 )$$

Ideally, when R1=R2>ΔR, the equation can be simplified:

$$V 1 - V 2 \approx \frac{- 2 Δ R }{R 2 + R 1} {V}_{bias} \qquad ( 2 )$$

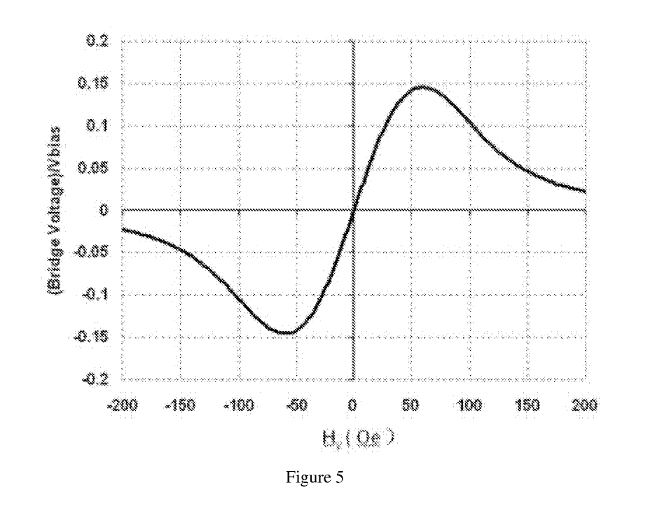

The simulated response for this push-pull bridge circuit is shown in FIG. 5.

The required magnetization angle between the ferromagnetic free layer and the ferromagnetic pinned layer may be achieved in the following ways:
(1) Shape Anisotropy: Use shape anisotropy of the MTJ element to create easy magnetization axes, in order to bias the magnetic free layer magnetization directions. Shape anisotropy of the of the MTJ element is can be adjusted by changing the length relative to the width of the MTJ element, and also by rotating the elements;
(2) Permanent Magnet Bias: Set permanent magnets around the MTJ element to produce a field to bias the free layer magnetization direction;
(3) Coil Bias: Deposit metal wires used to carry a current for generating a magnetic field in layers above or below the MTJ elements, in order to produce a field to bias magnetic free layer directions;
(4) Neel Coupling: Use the Neel Coupling field between the ferromagnetic pinned layer and the ferromagnetic free layer to bias ferromagnetic free layer magnetization;
(5) Exchange Bias: In this technique, weak exchange coupling to an adjacent antiferromagnetic layer on the freelayer creates an effective bias field. The strength can be tuned by placing a Cu or Ta layer between the antiferromagnetic layer and the freelayer, which reduces the strength of exchange bias.

### Referenced Full-Bridge Magnetic Sensor Design:

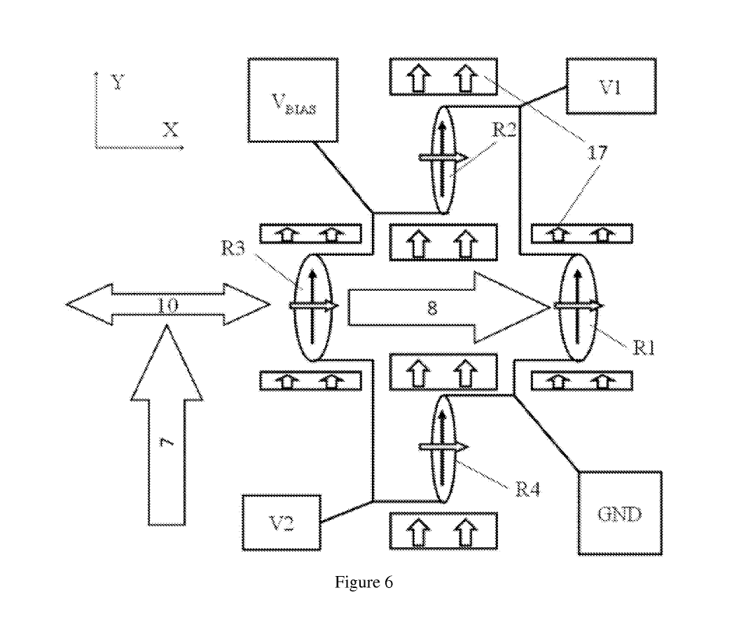

FIG. 6 shows a schematic diagram of a referenced full bridge MTJ sensor. Here, four MTJ magnetoresistive elements R1, R2, R3 and R4 are interconnected to form a bridge, and each magnetoresistive element is composed of one or more MTJs connected in series (FIG. 2). In this design, the output curve of magnetoresistive elements R1 and R3 are strongly dependent on the applied magnetic field 9, and these elements are referred to as the sensing arms. The magnetoresistive response of elements R2 and R4, on the other hand, is only weakly dependent on the applied magnetic field 9, and these elements are called the reference arms. The sensitive direction of this referenced full-bridge structure 10 is parallel to the pinning direction 8. This specific referenced bridge design utilizes the same ferromagnetic pinned layer direction for all bridge arms, and it can thus be built on the same chip as the push-pull full bridge sensor, without the use of a multi-chip packaging process or local laser heating.

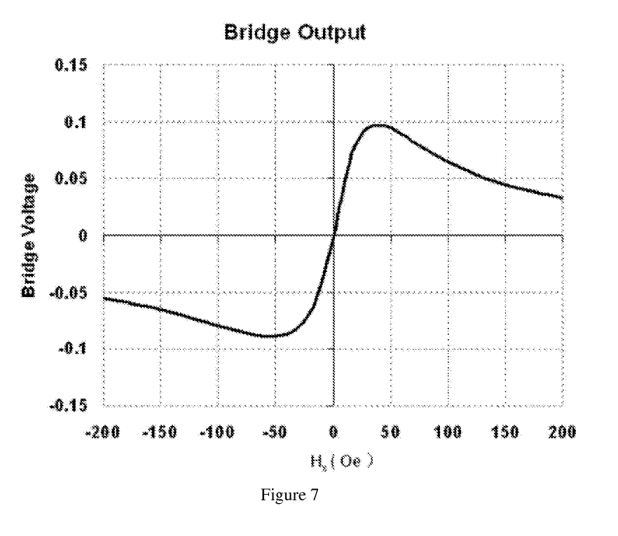

When a field is applied to the referenced push-pull full bridge sensor, the magnetic field component along the sensitive direction causes the sensor arms R1 and R3 to increase or decrease in resistance, while the reference arm elements R2 and R4 do not change much. In practice, the output of the referenced MTJ full-bridge sensor is linear over a wide field range. A simulation output response curve is shown in FIG. 7.

In order to build a practical referenced bridge sensor, it is important to set different sensitivities for the sense and reference arms. The sensitivity of a magnetoresistive element is defined as the change in resistance as a function of applied magnetic field:

$${S}_{MTJ} = \frac{1}{2} ( \frac{{R}_{H} - {R}_{L}}{{R}_{H} + {R}_{L}} ) ( \frac{{V}_{bias}}{{H}_{5}} ) \qquad ( 3 )$$

It is not practical to reduce the magnetoresistance of the reference arm with respect to the sensor arm, so the relative change in sensitivity between the reference and sense arms is best accomplished by changing H. This can be accomplished through any one of or a combination of the following methods:
(1) Magnetic Shielding: A high permeability ferromagnetic layer is deposited over the reference arm in order to attenuate the applied magnetic field;
(2) Shape Anisotropy: Pattern the reference and the sense elements into different sizes; therefore have different shape anisotropy energies and thus different sensitivities. It is most common to vary the length to width ratio of the sensing elements such that the demagnetizing field of the reference elements is much larger than the demagnetizing fields of the sensing elements ;
(3) Exchange Bias: This technique is used to create a bias field on the free layer of the MTJ element perpendicular to the sensitive direction of the MTJ element by using weak exchange coupling to an antiferromagnetic layer. A Cu or Ta barrier layer may be provided between the free layer and the exchange bias layer to reduce the strength of the exchange bias;
(4) In-Stack Bias: In this technique, permanent magnet alloys of Fe, Co, Cr or Pt are deposited onto the surface of the sensor element of the magnetic tunnel junction, and the resulting stray field biases the MTJ element 1. A large magnetic field can then be used to initialize the sensor at different angles. A very important advantage is that the bias field can eliminate the magnetic domains in the MTJ element to improve the stability and linearity of the MTJ element, and the direction of the magnetization can be adjusted to provide great flexibility in tuning the response.

### Single-Chip Biaxial Magnetic Sensor Design:

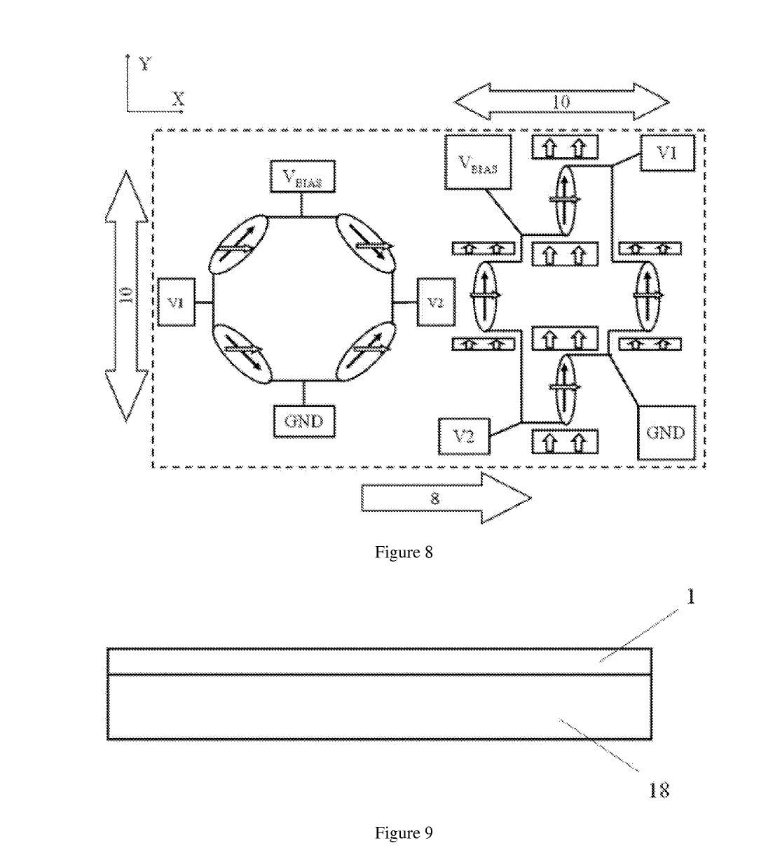

Because the sensors are comprised of magnetoresistive films deposited simultaneously on the same wafer, the pinned layer magnetization directions of the areas used to make different sensor axes are the same. Unfortunately, the biaxial magnetic field sensors consist of two bridge sensors that must be rotated at a 90° angle with respect to each other. In the following we will describe the realization of the single chip biaxial magnetic field sensor. Single chip MTJ-axis magnetic field sensor design can be achieved through the following methods or combination of several methods:
Method 1: Local Laser Heating: After deposition the pinned layers of the different sensor bridges are aligned parallel to each other. A local laser pulse may be applied in the presence of a magnetic field to realign the pinned layer in specific areas;
Method 2: Multiple Depositions: Different magnetoresistive films may be deposited on different areas of the chip to achieve the correct pinned layer orientation for each sensor.
Method 3: Referenced/Push-Pull: A single chip MTJ biaxial magnetic field sensor may be achieved as shown on FIG. 8. Full bridge and referenced bridge sensors can be developed that are sensitive to fields parallel or perpendicular to the pinned layer direction. These full-bridge sensors can be built on the same substrate using the same steps and the same ferromagnetic pinned layer 8 set direction.

### Triaxial Magnetic Field Sensor Design:

A triaxial magnetic sensor comprising an X-axis bridge sensor 25 with a sensing direction along a X-axis, a Y-axis bridge sensor 26 that has a sensing direction along a Y-axis, a Z-axis sensor 27 that has a sensing direction along a Z-axis, wherein the X-axis, the Y-axis, and the Z-axis are mutually orthogonal; an ASIC chip 19 is connected with and matched to the X-axis 25, the Y-axis 26, and the Z-axis 27 sensor bridges; said Z-axis sensor 27 includes several interconnected magnetic sensor chips 24 and each of the interconnected magnetic sensor chips 24 is comprised of a substrate 18 onto which a MTJ element 1 is deposited, and each of the interconnected magnetic sensor chips 24 is positioned on the ASIC chip 19 along an attachment edge 21, said attachment edge 21 is adjacent to the surface edge 22, and it is oriented at an angle 23 with respect to the MTJ element edge 22, wherein said angle 23 is an acute angle or an obtuse angle. The ASIC chip 19 is used for signal conditioning.

The X-axis bridge sensor 25 and the Y-axis bridge sensor 26 are integrated into the same chip. Said X-axis bridge sensor 25 is a MTJ sensor. Said Y-axis bridge sensor 26 is a MTJ sensor. Said X-axis bridge sensor 25 is a referenced bridge sensor and the Y-axis bridge sensor 26 is a push-pull bridge sensor.

Said magnetic sensor chip 24 through the solder balls 20 and the ASIC chip 19 are electrically interconnected.

The Z-axis sensor 27 includes two or four MTJ magnetic sensor chips 24, said MTJ sensor chips 24 are symmetrically arranged on the ASIC chip 19.

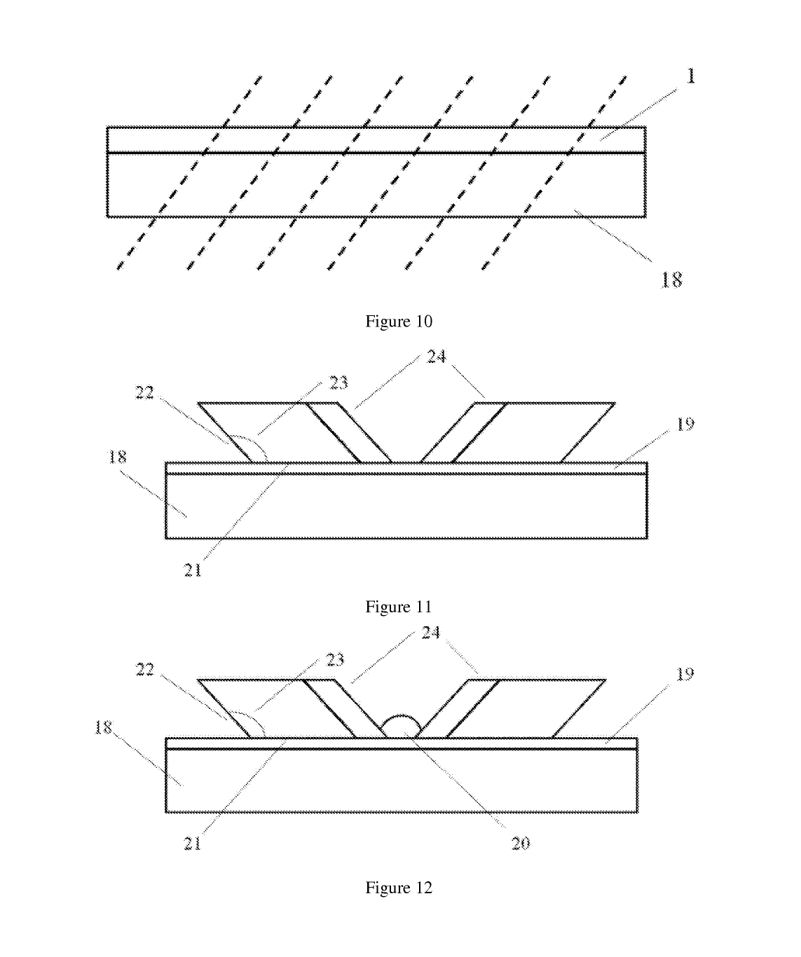

In order to form a triaxial bridge sensor as shown in FIG. 17, a first MTJ packaging method includes the following steps: A) fabricating a X-axis bridge sensor 25 that has a sensing direction along a X-axis and is electrically connecting the X-axis sensor with ASIC chip 19; B) fabricating a Y-axis bridge sensor 26 that has a sensing direction along a Y-axis and is electrically connecting the Y-axis sensor with ASIC chip 19; C) fabricating MTJ magnetoresistive elements 1 on a wafer 18 as shown in FIG. 9, cutting said MTJ wafer obliquely to form MTJ magnetic sensor chips 24 as shown in FIG. 10; placing the attachment edge 21 of the MTJ magnetic sensor chips 24 onto the ASIC chip 19 as shown in FIG. 11; Wherein each said attachment edge 21 is at an angle with respect to the adjacent surface 22 of the substrate, and the angle 23 is an acute angle or an obtuse angle; physically connecting each of the MTJ magnetic sensor chips 24 with the ASIC chip 19 using solder bumps 20 as shown in FIG. 12; and electrically connecting the MTJ magnetic sensing elements 24 to form a Z-axis magnetic sensor 27.

The MTJ magnetic sensor chip 24 can be a bridge type magnetic field sensor chip can be fabricated in one step as shown in FIGS. 4 and 6, but it may also be comprised of magnetoresistive elements chips as shown in FIG. 3 that are interconnected in order to form a magnetic sensor bridge.

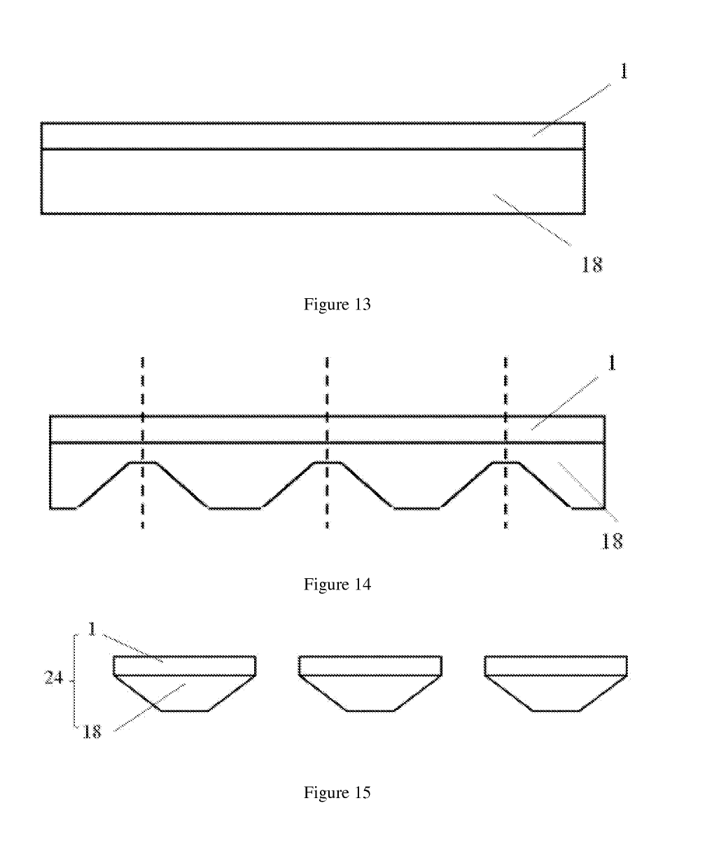

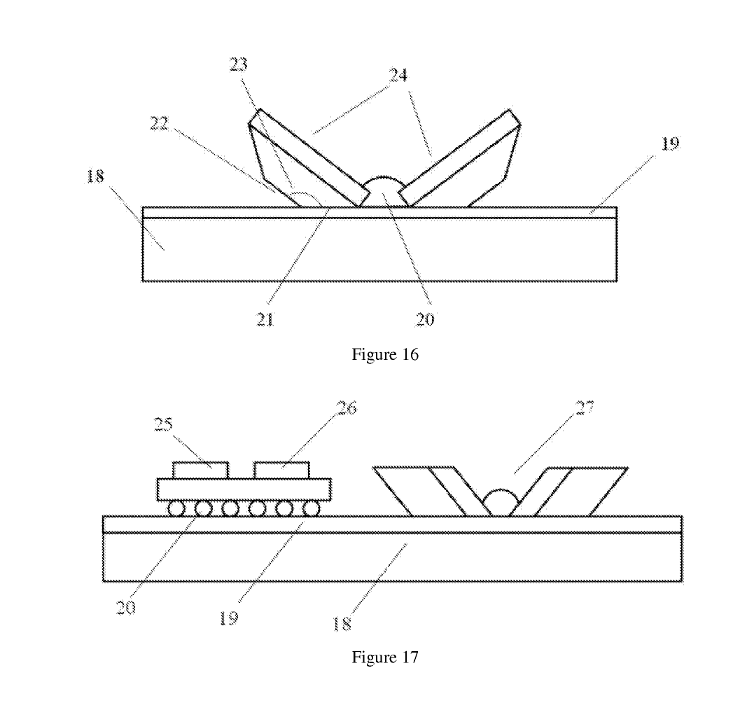

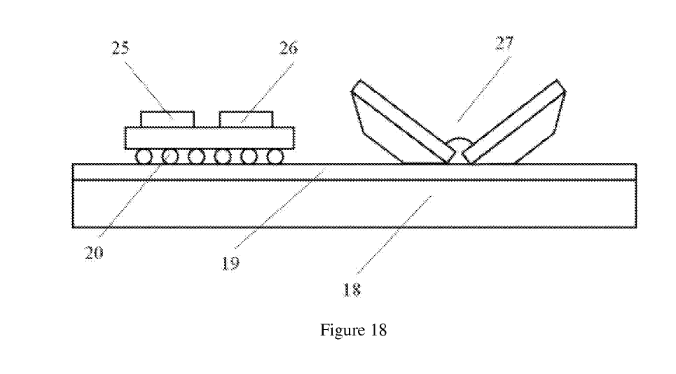

FIG. 18 shows a second preparation method for building a triaxial MTJ magnetic field sensor, comprising the steps of A) fabricating a X-axis magnetic field sensor bridge 25 that has a sensing direction along a X-axis and electrically connecting the X-axis sensor to ASIC chip 19; B) fabricating a Y-axis magnetic field sensor bridge 26 that has a sensing direction along a X-axis and electrically connecting the X-axis sensor to ASIC chip 19; and C) fabricating MTJ magnetoresistive elements 24 on a wafer 18 as shown in FIG. 13; preparing the backside of the 12 wafer for connection to the ASIC chip 19 by etching the back side of said wafer to form a slopes; cutting the MTJ wafer to form MTJ magnetic sensor chips 24 as shown in FIGS. 14 and 15; placing the attachment edge 21 of the MTJ magnetic sensor chips 24 onto the ASIC chip 19; each said attachment edge 21 is at an angle 23 with respect to the adjacent surface of the substrate 22, and the angle 23 is an acute angle or an obtuse angle; physically connecting each of the MTJ magnetic sensor chips 24 with the ASIC chip 19 using solder bumps 20 as shown in FIG. 16; and electrically connecting the MTJ magnetic sensing elements 24 to form a Z-axis magnetic sensor 27.

The MTJ magnetic sensor chip 24 can be a bridge type magnetic field sensor chip as shown in FIGS. 4 and 6, but it may also be comprised of magnetoresistive elements chips as shown in FIG. 3 that are interconnected in order to form a magnetic sensor bridge.

The above described embodiments demonstrate specific implementations of the present invention, and obviously other specific implementations exist that do not exceed the scope or spirit of the present invention. It will be apparent to those skilled in the art that various modifications can be made to the present invention without departing from the scope or spirit of the invention.

1. A triaxial MTJ sensor, comprising an X-axis bridge sensor with a sensing direction along a X-axis, a Y-axis bridge sensor that has a sensing direction along a Y-axis, a Z-axis sensor that has a sensing direction along a Z-axis, wherein the X-axis, the Y-axis, and the Z-axis are mutually orthogonal; an ASIC chip is connected with and matched to the X-axis bridge sensor , the Y-axis bridge sensor, and the Z-axis sensor; said Z-axis sensor includes several interconnected magnetic sensor chips and each of the interconnected magnetic sensing chips is comprised of a substrate onto which a MTJ element is deposited, said interconnected z-axis sensor chips are positioned on the ASIC chip along an attachment edge, wherein said attachment edge is oriented at an angle with respect to an adjacent z-axis sensor chip surface, wherein said angle is an acute angle or an obtuse angle. The ASIC chip is used for signal conditioning.

2. A triaxial MTJ sensor as in claim 1, wherein the X-axis bridge sensor is a MTJ sensor.

3. A triaxial MTJ sensor as in claim 1, wherein the Y-axis bridge sensor is a MTJ sensor.

4. A triaxial MTJ sensor as in claim 1, wherein the X-axis bridge sensor and the Y-axis bridge sensor are connected with the ASIC chip using gold wire bonds.

5. A triaxial MTJ sensor as in claim 1, wherein the X-axis bridge sensor and the Y-axis bridge sensor are connected with the ASIC chip using solder bumps.

6. A triaxial MTJ sensor as in claim 1, wherein the X-axis bridge sensor and the Y-axis bridge sensor are integrated into the same chip.

7. A triaxial MTJ sensor as in claim 4, wherein the X-axis bridge sensor is a referenced bridge sensor and the Y-axis bridge sensor is a push-pull bridge sensor.

8. A triaxial MTJ sensor as in claim 1, wherein each of the magnetic sensor chips is connected with the ASIC chip using solder bumps.

9. A triaxial MTJ sensor as in claim 1, wherein the Z-axis sensor includes two or four MTJ magnetic sensor chips, said MTJ sensor chips are symmetrically arranged on the ASIC chip.

10. A triaxial MTJ sensor packaging method, comprising the steps of
A) fabricating a X-axis bridge sensor that has a sensing direction along a X-axis and electrically connecting the X-axis sensor with an ASIC chip,
B) fabricating a Y-axis bridge sensor that has a sensing direction along a Y-axis and electrically connecting the Y-axis sensor with the ASIC chip,
C) fabricating MTJ magnetoresistive elements on a wafer, cutting said MTJ wafer obliquely to form MTJ magnetic sensor chips; placing the attachment edge of the MTJ magnetic sensor chips onto the ASIC chip; each said attachment edge is at an angle with respect to the adjacent surface of the substrate, and the angle is an acute angle or an obtuse angle; physically connecting each of the MTJ magnetic sensor chips with the ASIC chip using solder bumps; and electrically connecting the MTJ magnetic sensing elements to form a Z-axis magnetic sensor.

11. A MTJ three-axis sensor packaging method, comprising the steps of
A) fabricating a X-axis magnetic field sensor bridge that has a sensing direction along a X-axis and electrically connecting the X-axis sensor to an ASIC chip,
B) fabricating a Y-axis magnetic field sensor bridge that has a sensing direction along a X-axis and electrically connecting the X-axis sensor to the ASIC chip,
C) fabricating MTJ magnetoresistive elements on a wafer, etching the back side of said wafer to form a slopes; cutting the MTJ wafer to form MTJ magnetic sensor chips; placing the attachment edge of the MTJ magnetic sensor chips onto the ASIC chip; each said attachment edge is at an angle with respect to the adjacent surface of the substrate, and the angle is an acute angle or an obtuse angle; physically connecting each of the MTJ magnetic sensor chips with the ASIC chip using solder bumps; and electrically connecting the MTJ magnetic sensing elements to form a Z-axis magnetic sensor.
